(19) United States
(12) Patent Application Publication
(10) Pub. No.: US 2011/0299694 A1
(43) Pub. Date: Dec. 8, 2011

(54) AUDIO EXTENSION SYSTEM

(76) Inventors: Fu-Chun YEN, New Taipei City (TW); Yamagami Hiroyuki, Saitama (JP)

(21) Appl. No.: 13/106,313

(22) Filed: May 12, 2011

(30) Foreign Application Priority Data
May 13, 2010 (JP) JP2010-111174

(51) Int. Cl. H03G 3/00

(52) U.S. Cl. 381/62

(57) ABSTRACT

The present invention discloses an audio extension system. The audio extension system comprises a permanent magnet; a holder having a concave portion for holding the permanent magnet; a tube disposed at a gap between a side of the permanent and a side of the concave portion of the holder for holding a coil surrounded a periphery of the permanent magnet and supported the coil to vibrate freely; and a conducting part, mounted at one end of the tube for vibration to a vibrating member disposed therein; wherein two ends of a conducting cable formed the coil are directly connecting to a jack of an earphone or a headphone of outputting an audio signal, and the conducting part on the audio signal outputted from the jack is conducting the vibration of the coil through the tube to output a sound from the vibrating member.

### TECHNICAL FIELD

This invention relates to an audio extension system, wherein the audio extension system is capable of having the sound the same as a speaker while the audio extension system is attached on vibrating member, such like a cardboard box, a carton, a tube, or a plate member, without using a booster amplifier.

### BACKGROUND OF THE INVENTION

Recently, the electronic devices, such like personal computer, music player, or mobile phone, are widely used. Each of the electronic devices is including a jack for providing an earphone or a headphone to be connected. Traditionally, the earphone or the headphone is connected with the jack of the electronic devices while listening to the sound. Either, a vibrating speaker disclosed by the registered U.S. Pat. No. 3,136,207 is connecting the jack while listening to the sound so as to conduct the sound through a vibrating member and then output the sound.

### SUMMARY OF THE INVENTION

The vibrating speaker disclosed by the registered U.S. Pat. No. 3,136,207 is not a inconveniently carried speaker. The advantage is that a vibrating member is capable of outputting a sound the same as the one outputted from the resonating speaker if the vibrating speaker is connecting to the vibrating member capable of conducting sounds.

However, the voltage of the audio signal outputted from the jack is only sufficient to drive the earphone or the headphone. The disadvantage is that the vibrating speaker must use a booster amplifier to amplify the audio signal while the vibrating member outputs the sound the same as the resonating speaker.

It is convenient to use the vibrating member capable of conducting sounds to be a speaker. But a booster amplifier is necessary. In addition, the power supply for the booster amplifier still needs to be improved in mobility and convenience for use.

The objective of this invention is providing an audio extension system, which is capable of having the sound the same as a speaker while the audio extension system is attached on vibrating member, such like a cardboard box, a carton, a tube, or a plate member, without using a booster amplifier, has excellent movability and convenience for use, and is capable of being an accessory to carry around.

To achieve above objective, this invention provides an audio extension system, which comprises: a permanent magnet; a holder having a concave portion for holding the permanent magnet; a tube disposed at a gap between a side of the permanent and a side of the concave portion of the holder for storing a coil surrounded a periphery of the permanent magnet and supported the coil to vibrate freely; and a vibrating member, attached at one end of the tube for vibrate a vibrating member disposed therein; wherein two ends of a conducting line formed the coil are directly connecting to a jack of an earphone or a headphone for outputting an audio signal, and the vibrating member based on the audio signal outputted from the jack is conducting the vibration of the coil through the tube to output a sound from the vibrating member.

Therefore, the audio extension system is capable of having the sound the same as a speaker while the audio extension system is attached on vibrating member, such like a cardboard box, a carton, a tube, or a plate member, without using a booster amplifier, has excellent movability and convenience for use, and is capable of being an accessory to carry around.

Other features or advantages of the present invention will be apparent from the following drawings and detailed description of several embodiments, and also from the appending claims.

### BRIEF DESCRIPTION OF THE DRAWINGS

FIG. 1 shows a combination diagram of the audio assembly according to this invention.

FIG. 2 shows an exploded diagram of the audio assembly according to this invention.

FIG. 3 shows a cross-section diagram of the vibrating set according to this invention.

### DETAILED DESCRIPTION OF THE INVENTION

The specific examples below are to be construed as merely illustrative, and not limitative of the remainder of the disclosure in any way whatsoever. Without further elaboration, it is believed that one skilled in the art can, based on the description herein, utilize the present invention to its fullest extent. All publications cited herein are hereby incorporated by reference in their entirety. Further, any mechanism proposed below does not in any way restrict the scope of the claimed invention.

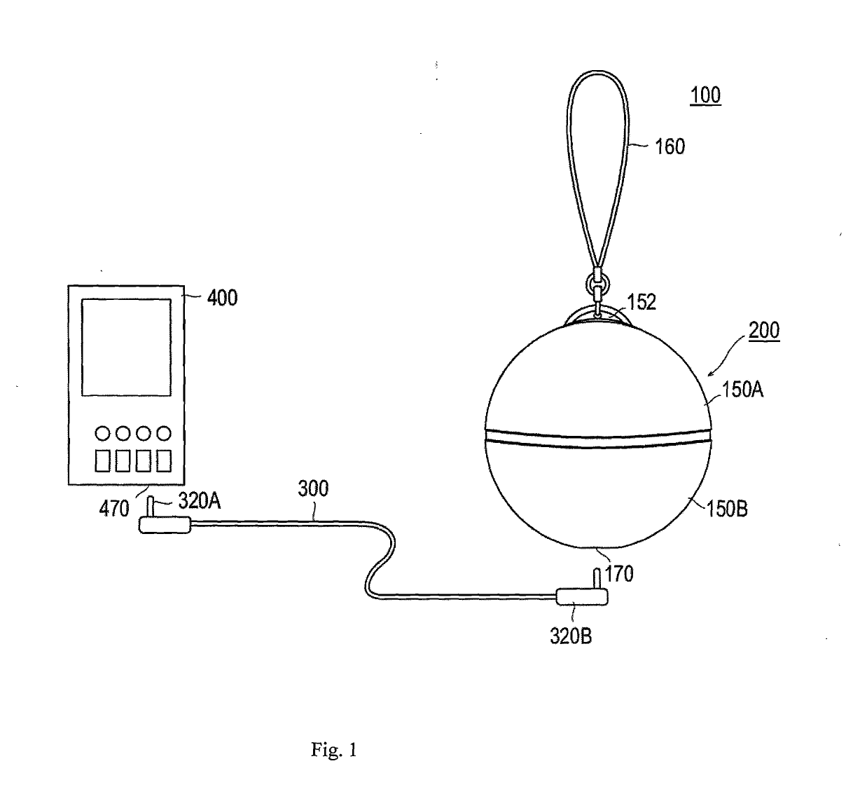

Please refer to FIG. 1 an audio extension system 100 comprises a main body 200 and a connecting cable 300.

The main body 200 is formed by two half case 150A, 150B with hemisphere shape. The half cases 150A, 150B are capable of being divided and assembled.

The half cases 150A, 150B are hollow. A protruding portion 152 is formed on the top of the half case 150A, and a through hole (not numbered) is formed on the protruding portion 152 for providing a strap 160 to be passed through. Therefore, the strap 160 is installed on the half case 150A so as to be capable of carrying the main body 200. A socket 170 is mounted at the top of the half case 150B so as to store a vibrating set (described later). The socket 170 is capable of easily being inserted the connecting cable 300, even the main body 200 is attached on a vibrating member. The vibrating member is one thing that is capable of outputting a sound the same as the speaker while the vibrating set is mounted in the half case 150B, such like a cardboard box, a carton, a tube, or a plate member, and resonated by the vibrating set.

A hole around the socket 170 and an outer surface of top of the half case 150B are assembled as a plate form for uneasily seeing the socket 170 from outside and considering the design of the main body 200. The half cases 150A, 150B is formed by materials with insulation plastic or resin. The half cases 150A, 150B shown as FIG. 1 do not perform any color or pattern. But they can be colored in red, green, blue, or yellow, and performed the patterns, such like a geometric pattern, a figure of drawing, a scene, or a character.

The main body 200 is connected to the jack of an electronic device, such like a personal computer, a music player, or a mobile phone, through the connecting cable 300.

Two male connectors 320A and 320B are respectively connected to two ends of the connecting cable 300. The male connector 320B of the connecting cable 300 is inserted to the socket 170 of the main body 200, and the male connector 320A of the connecting cable 300 is inserted to the socket 470 of the electronic device 400, so that the main body 200 is capable of electrically connecting with the electronic device 400. Generally, one end of the connecting cable 300 is mounted a male connector, and connect the other end of the connecting cable 300 is a female connecting base. But two ends of the connecting cable 300 of this embodiment are respectively mounted two male connectors 320A and 320B. If the main body 200 is use a male connector, the male connector is protruded outwardly and obviously injured the design of the main body 200. It is easy to damage the mounting portion between the main body 200 and the connecting cable 300 while the main body 200 is dropped or crashed.

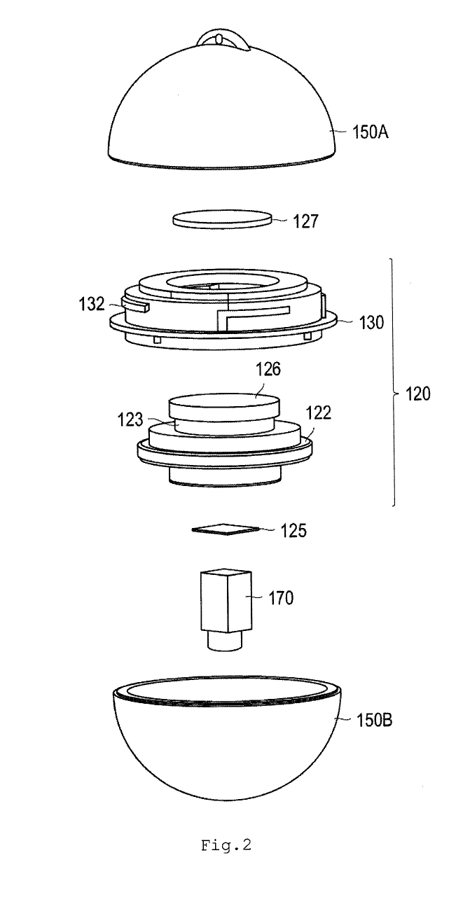

Please refer to FIG. 2, there is nothing disposed inside the half case 150A of the main body 200. But a vibrating set 120 and a socket 170 are inside the half case 150B.

The vibrating set 120 is capable of outputting sounds through a vibrating member, such like a cardboard box, a carton, a tube, or a plate member.

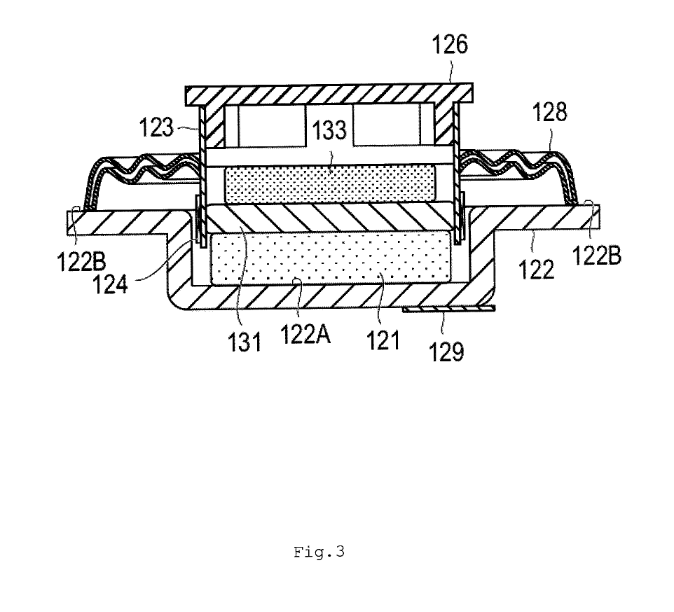

The vibrating set 120 comprises a permanent magnet 121 (shown as FIG. 3), a holder 122 for supporting the permanent magnet 121, a paper tube 123 made from a high strength paper to form a tube, a coil 124 (shown as FIG. 3) wound and fixed at the periphery of the paper tube 123, an insulating plate 125 for preventing the two ends of the coil 124 and the conducting line (not shown) of the terminal socket170 from contacting the holder 122, a conducting part 126 for efficiently conducting the vibration of the paper tube 123 to the vibrating member, a adhesive pad 127 for providing the conducting part 126 to be attached on the vibrating member, and a holding member 130 for supporting the holder 122.

The holder 122 of the vibrating set 120 is supported by the holding member 130. The holding member 130 is assembled at the half case 150B. The holding member 130 includes a connecting portion 132 for providing the half case 150A to be connected to the half case 150B. A space between the vibrating set 120 and the half case 150B is defined while the holding member 130 is assembled to the half case 150B, so that an echo is generated and a sound pressure of the sound is increased. Therefore, the vibrating set 120 is capable of efficiently outputting the sounds from the vibrating member, and there is no necessary to set a booster amplifier between the electronic device 400 and the main body 200.

The half case 150A is connected with the half case 150B contain the vibrating set 120 and the socket 170 through the holding member 130. Especially, the vibrating set 120 adjacent to the conducting part 126 is capable of preventing the direct attack from outside. Meanwhile, the half case 150A and 150B are combined in one by the holding member 130, so as to perform the excellent design of the main body 200 and make the main body 200 be capable of using as an accessory or an ornament to carry around.

The circular shape of the main body 200 is only for example, but not limited thereto. It could be triangle, square, polygon, or characters.

The audio extension system 100 of this invention is capable of outputting the sounds the same as a speaker without using a booster amplifier by attaching the main body 200 to the vibrating member.

Even only directly inputting a voltage of the audio signal from the socket 170 of the electronic device 400, it is capable of getting sufficient power. And the critical characteristics are focused on the permanent magnet 121, holder 122, the coil 124, and the conducting part 126.

The permanent magnet 121 is made from an anisotropic Ferrite magnet or a Neodymium magnet with large magnetic flux density.

The holder 122 is made by a metal with large permeability which prevents the magnetic flux of the permanent magnet 121 from draining.

In order to make the coil 124 be capable of conducting larger current and decreasing the resistance and impedance, the thickness and the numbers of the loops of the coil 124 is critical. For example, the resistance of the coil is less than al in a frequency of 1000 Hz.

The conducting part 126 is made from a plastic material with light weight and high strength, so as to directly contact the vibrating member to conduct the vibration and efficiently conducting the micro vibration of the coil 124 through the paper tube 123.

The conducting part 126 includes an adhesive pad 127 for easily attach on the vibrating member. The adhesive pad 127 is capable of adhering several times because the adhesion of the contacting surface on the vibrating member should be less. The double-sided tape is capable of replacing the adhesive pad 127. An absorbing plate is capable of being-attached on the conducting part126 to replace the adhesive pad 127 and the double-sided tape. In addition, the adhesive pad 127 or the double-sided tape is preferable to prevent form the sound attenuation.

The insulating plate 125 prevents the two ends of the coil 124 and the terminal of the socket 170 of the conducting line from contacting the holder 122 to short.

Please refer to FIG. 3 the holder 122 is circular viewed in vertical direction. The holder 122 includes a concave portion 122A with cylindrical shape for holding the permanent magnet 121. A flat portion 122B with circular flange is formed at the periphery of the concave portion 122A. The holder 122 has an inversion of a hat shape.

The concave portion 122A of the holder 122 is holding the cylindrical permanent magnet 121, what the diameter of the permanent magnet 121 is smaller than the one of the concave portion 122A. The bottom surface of the permanent magnet 121 and the bottom surface of the concave portion 122A are contacting closely without gap. A washer 131 made from a metal with large permeability is mounted on the permanent magnet 121. And another permanent magnet 133 is mounted on the washer 131. The washer 131 is sealed at the permanent magnet 121 without gap, and the permanent magnet 133 is sealed at the washer 131 without gap. If the gap is appeared, part of the magnetic flux of the permanent magnet 121 and 133 is drained and can not be conducted to the holder 122 or washer 131, and further the magnetic force is decreased. The N poles and S poles of the permanent magnet 121 and 133 are set relative to each other through the washer 131. The washer 131 is vertical to the magnetic flux direction of the permanent magnet 121 and 133 to prevent the magnetic flux from draining.

A connecting base board 129 is disposed outside the concave portion 122A of the holder 122 and mounted from the side surface of the concave portion 122A to the coil 124 disposed on the flat portion 122B. Therefore, the socket 170 is connected to the coil 124 through the connecting base board 129.

A gap allowed the paper tube 123 to move freely and axially is formed among the permanent magnet 121, the washer 131, the side surface of the permanent magnet 133, and the side surface of the holder 122. The gap between the washer 131 and the side surface of the holder 122 is substantially equal to the thickness of the paper tube 123. Therefore, the paper tube 123 is lead to washer 131 and the side surface of the holder 122 to move up and down (vibration).

The coil 124 is wound corresponding to the washer 131 because the magnetic force at the periphery of the washer 131 is the strongest, so that the sound pressure is increased by the structure including the permanent magnet 121, washer 131, permanent magnet 133, and the coil 124. The main body 200 of this invention vibrates the vibrating member through the electric signal from the socket 470 of the electronic device 400 without using a booster amplifier. The magnetic flux drain is capable of affecting the performance, especially decreasing the power. Preventing the magnetic flux from draining is necessary. The holder 122 and the washer 131 are made from a metal with large permeability, so the magnetic force of the permanent magnetic 121, 133 is efficiently acting on the coil 124.

The paper tube 123 is arranged outside to surround the permanent magnetic 121, the washer 131, and the permanent magnet 133. The coil 124 wound around the paper tube 123 is covering outer ring of the periphery of the washer 131. The paper tube 123 and coil 124 are fixed by adhesives.

The paper tube 123 is used for making the audio signal be conducted to the coil 124 and freely vibrated among the permanent magnet 121, the washer 131, the side surface of the permanent magnet 133, and the side surface of the holder 122. And the paper tube 123 must be arranged outside the permanent magnet 121 while the bottom surface of the holder 122 is floating. Therefore, the paper tube 123 is capable of freely vibrating by a damper 128 mounted at the flat portion 122B of the holder 122.

The damper 128 is formed a donut shape extending the shape of the flat portion 122B and the cross-section viewed in vertical direction of the damper is waved. The paper tube 123 inserted in the damper 128 is capable of freely vibrating by the support of the damper 128. The diameter of the paper tube 123 is equal to or larger than the diameter of the hollow portion of the damper 128. The damper 128 and the periphery of the paper tube 123 are adhered to fix each other by an adhesive. The periphery of the damper 128 is adhered to the flat portion 122B of the holder 122 by the adhesive.

Therefore, when the coil 124 is vibrating toward the axial direction of the permanent magnet 121, the paper tube 123 supported by and vibrated simultaneously with the damper 128 is vibrating toward the axial direction thereof.

The front end portion of the paper tube 123 is mounted in the conducting part 126. The diameter of the conducting part 126 is larger than the paper tube 123. The conducting part 126 is a disc-shaped plastic to block the through hole of the paper tuber 123. So as to ensure that there is sealing quality without air leakage between the open portion disposed at the front end portion of the paper tube 123 and the conducting part 126. One end of the conducting part 126 is disc shape, and the other end is formed several protrusions embedded to the inner periphery of the paper tube 123. The conducting part 126 is connected to the inner surface of the paper tuber 123 through the protrusions and mounted at the front end portion of the paper tube 123. Meanwhile, the outside of the disc-shaped end of the conducting-part 126 is temporarily adhered the adhesive pad 127 to make the conducting part 126 be attached on the vibrating member.

The conducting part 126 is disc shape and assembled at the open portion of the paper tube 123, so that the conducting part 126 is capable of conducting the sounds (vibration) to the vibrating member without decaying the vibration of the coil 124. The disc-shaped conducting part 126 is better than the donut-shaped one because the disc-shaped conducting part 126 is capable of sealing the air pressure in the paper tube 123 and efficiently performing the force for pushing the conducting part 126, so as to efficiently conduct the vibration to the conducting part 126. The donut-shaped conducting part 126 will cause the air leakage from the hollow portion, so that the vibration can not be efficiently conducted to the conducting part 126.

The weight should be considered, so that the conducting part 126 is capable of conducting the sounds (vibration) to the vibrating member without decaying the vibration of the coil 124. It is hard to perform a high pitch while the weight of the conducting part 126 is heavier. Therefore, the weight of the paper tuber 123, the coil 124, and the conducting part 126, and the actuation of the damper 128 are critical. In order to efficiently output sounds from the vibrating member and make the frequency of the sounds flat as far as possible, continuously serious experiments are necessary.

The process of using of the audio extension system 100 mentioned above is described as below.

First of all, the half case 150A of the main body 200 is rotated to separate the half case 150B from the connecting portion 132 of the holding member 130. The conducting part 126 is exposed from the open side of the half case 150B. The surface of the conducting part 126 is adhered an adhesive pad 127 to make the contacting surface contact the vibrating member. Then, the half case 150B is attached on the vibrating member.

The male connector 320B of the connecting cable 300 is inserted in the socket 170 of the half case 150B, and the male connector 320A of the connecting cable 300 is inserted in the socket 470 (ex. the jack of the earphone) of the electronic device 400. It is easy to connect the male connector 320B while the half case 150B is attached on the vibrating member because the socket 170 is disposed at the top of the half case 150B and the force of inserting the male connector 320B is pushed toward the vibrating member.

After the electronic device 400 is outputting audio signals, the vibrating between the permanent magnet 121 and coil 124 is generated corresponding to the audio signals and further the vibration is conducted to the paper tube 123 and conducting part 126 to make the vibrating member be vibrated while the connecting cable 300 is connected to the main body 200. An echo is generated between the vibrating set 120 mounted at the holding member 130 and the space defined by the half case 150B to increase the sound pressure.

The vibrating member is outputting sounds with sound pressure the same as a speaker. Furthermore, the sound pressure is not larger than the speaker with a booster amplifier, but it is sufficient to enjoy the music or present in office.

After using, the conducting cable 300 is disconnected from the half case 150B and the electronic device 400. And after the half 150B is disconnected from the vibrating member, the half case 150A then combine and turn the half case 150B. Next, the main body 200 is capable of fastening at a carrying bag through the strap 160, so that the main body 200 is capable of being an accessory or decoration and easy to carry.

The audio extension system 100 is easy and convenient to carry because there is not necessary to use a booster amplifier and the power source for the booster amplifier. And it is capable of lowering the production cost and enforcing the reliability while the elements are reduced (without the booster amplifier and the power source of the booster amplifier). The audio extension system 100 is capable of being an accessory or decoration to carry around.

From the above description, one skilled in the art can easily ascertain the essential characteristics of the present invention, and without departing from the spirit and scope thereof, can make various changes and modifications of the invention to adapt it to various usages and conditions. Thus, other embodiments are also within the claims.

1. An audio extension system, comprising:
a permanent magnet;
a holder, having a concave portion for holding the permanent magnet;
a tube, disposed at a gap between a side of the permanent and a side of the concave portion of the holder for storing a coil surrounded a periphery of the permanent magnet and supported the coil to vibrate freely; and
a conducting part, mounted at one end of the tube for vibration to a vibrating member disposed therein;
wherein two ends of a conducting cable formed the coil are directly connecting to a jack of an earphone or a headphone for outputting an audio signal, and the conducting part on the audio signal outputted from the jack is conducting the vibration of the coil through the tube to output a sound from the vibrating member.

2. The audio extension system of claim 1, wherein the vibrating set is stored in a main body capable of being divided into two half case, a socket is mounted inside one of the half case and inserted a male connector of the connecting cable, and the socket is connecting the two ends of the conducting line formed the coil.

3. The audio extension system of claim 2, wherein a space is formed between the vibrating member and the half case received the vibrating set to increase a sound pressure of the sound.

4. The audio extension system of claim 1, wherein the vibrating part is a shape of circular disc, and an adhesive pad is attached on the vibrating member corresponding to a contacting surface of the vibrating member.

5. The audio extension system of claim 1, wherein the permanent magnet is an anisotropic Ferrite magnet or a Neodymium magnet with large magnetic flux density, and a resistance of the coil is less than 2Ω in a frequency of 1000 Hz.
